(19) United States
(12) Patent Application Publication
(10) Pub. No.: US 2025/0173488 A1
(43) Pub. Date: May 29, 2025

(54) DECOUPLING STRUCTURAL PALEO DISSOLUTION IN THE CHARACTERIZATION OF NATURALLY FRACTURED CARBONATE RESERVOIRS

(71) Applicant: Saudi Arabian Oil Company, Dhahran (SA)

(72) Inventors: Karla Olvera Carranza, Dhahran (SA); Otto Meza Camargo, Dhahran (SA); Mohamed Bouaouaja, Dhahran (SA)

(21) Appl. No.: 18/521,163

(22) Filed: Nov. 28, 2023

(51) Int. Cl. G06F 30/28

(52) U.S. Cl. CPC G06F 30/28

(57) ABSTRACT

A method for characterizing naturally fractured carbonate reservoirs by decoupling structural paleo dissolution (SPD). A natural fracture model may be determined from reservoir parameters, and a fracture density index having a raster map representing fracture density may be determined from the natural fracture model. Structural paleo dissolution indicators may be identified using a well log such as a borehole image log. A three-dimensional structural paleo dissolution (SPD) model may be determined using the structural paleo dissolution (SPD) indicators and the fracture density index (FDI) by structural paleo dissolution (SPD) voids in the fracture density index (FDI). A natural fracture sweet spot may be identified in the naturally fractured carbonate reservoir using the three-dimensional structural paleo dissolution (SPD) model.

### BACKGROUND

### Field of the Disclosure

The present disclosure generally relates to the production of hydrocarbons from subsurface reservoirs. More specifically, embodiments of the disclosure relate to characterizing naturally fractured carbonate reservoirs by accounting for structural paleo dissolution.

### Description of the Related Art

The extraction of hydrocarbon resources from reservoirs in rock formations may depend on a variety of factors. Some reservoirs may present particular challenges with respect to hydraulic fracturing and identifying suitable intervals for fracturing. Naturally fractured carbonate reservoirs may present such challenges. A variety of factors may pose different difficulties in exploitation of naturally fractured carbonate reservoirs. For example, different geological elements present in such reservoirs may each require different techniques for characterization, and it may be difficult to determine the effects of each element in simulations and evaluations of such reservoirs.

### SUMMARY

Naturally fractured carbonate reservoirs may be characterized geologically by three major elements which together contribute to the estimation of pore-volume and connectivity within the reservoir: rock matrix, natural fractures, and paleo dissolution cavities. Rock matrix may be characterized by conventional core-log analysis for subsequent 3D geostatistical population; however, natural fractures and paleo dissolution spaces present more challenges for characterization.

The second element, natural fractures, may be characterized according to the techniques described in U.S. Pat. No. 10,607,043 and titled “SUBSURFACE RESERVOIR MODEL WITH 3D NATURAL FRACTURES PREDICTION,” a copy of which is hereby incorporated by reference in its entirety.

The third element, paleo dissolution cavities, may also be referred to as “structural paleo dissolution” (SPD). Structural paleo dissolution refers to any diagenetic processes, wherein paleo fluids percolate preferentially through a highly dense natural fracture network, shaping considerable large voids along fracture planes and the adjacent zones. Such structural paleo dissolution processes involve the mechanical stratigraphy of the rocks and thus control the dissolution effects vertically within the reservoir.

Embodiments of the disclosure generally relate to capturing and representing structural paleo dissolution effects in a 3D grid-block model in terms of fluid conductivity.

In one embodiment, a method for characterizing a naturally fractured carbonate reservoir is provided. The method includes obtaining a plurality of reservoir parameters representing a respectively plurality of properties of the naturally fractured carbonate reservoir and forming a natural fracture model by processing the obtained plurality of reservoir parameters to identify the presence and extent of natural fractures at locations in the naturally fractured carbonate reservoir. The method also includes determining, by the data processing system and using the discrete fracture network, a fracture density index (FDI), such that determining, using the discrete fracture network, a fracture density index (FDI) includes generating a raster map from the discrete fracture network, the raster map representing a fracture density per area. The method further includes obtaining a well log characterizing the naturally fractured carbonate reservoir, such that the well log includes a borehole image log, identifying structural paleo dissolution (SPD) indicators in the naturally fractured carbonate reservoir using the well log, and determining a three-dimensional structural paleo dissolution (SPD) model using the structural paleo dissolution (SPD) indicators and the fracture density index (FDI), such that the determining includes identifying structural paleo dissolution (SPD) voids in the fracture density index (FDI). Additionally, the method includes identifying a sweet spot for natural fractures in the naturally fractured carbonate reservoir using the three-dimensional structural paleo dissolution (SPD) model.

In some embodiments, the method includes obtaining a plurality of measurements from one or wells accessing the naturally fractured carbonate reservoir, and determining the reservoir parameters from the plurality of measurements. In some embodiments, the reservoir parameters include seismic attributes from seismic surveys of the subsurface geological structure. In some embodiments, the reservoir parameters include rock and mechanical properties from geological models of the subsurface geological structure. In some embodiments, the reservoir parameters include structural restoration models of the subsurface geological structure. In some embodiments, the reservoir parameters include rock geological characterizations of the subsurface geological structure. In some embodiments, the reservoir parameters include reservoir engineering measures obtained from production from the naturally fractured carbonate reservoir. In some embodiments, the method includes determining a geological model of the naturally fractured carbonate reservoir using the reservoir parameters, such that forming a natural fracture model by processing the obtained reservoir parameters includes using a plurality of petrophysical properties from the geological model. In some embodiments, the method includes drilling a well in a subsurface geological structure to a location in the naturally fractured carbonate reservoir based on the identified sweet spot. In some embodiments, the method includes determining a total flow capacity using a rock matrix flow capacity for the naturally fractured carbonate reservoir, a fracture flow capacity for the for the naturally fractured carbonate reservoir, and a structural paleo dissolution (SPD) flow capacity for the naturally fractured carbonate reservoir. In some embodiments, the method includes providing the three-dimensional structural paleo dissolution (SPD) model to a reservoir simulation for a determination of fluid flow response in the naturally fractured carbonate reservoir.

In another embodiment, a non-transitory computer-readable storage medium having executable code stored thereon for characterizing a naturally fractured carbonate reservoir is provided. The executable code includes a set of instructions that causes a processor to perform operations that include obtaining a plurality of reservoir parameters representing a respectively plurality of properties of the naturally fractured carbonate reservoir and forming a natural fracture model by processing the obtained plurality of reservoir parameters to identify the presence and extent of natural fractures at locations in the naturally fractured carbonate reservoir. The operations also include determining, by the data processing system and using the discrete fracture network, a fracture density index (FDI), such that determining, using the discrete fracture network, a fracture density index (FDI) includes generating a raster map from the discrete fracture network, the raster map representing a fracture density per area. The operations further include obtaining a well log characterizing the naturally fractured carbonate reservoir, such that the well log includes a borehole image log, identifying structural paleo dissolution (SPD) indicators in the naturally fractured carbonate reservoir using the well log, and determining a three-dimensional structural paleo dissolution (SPD) model using the structural paleo dissolution (SPD) indicators and the fracture density index (FDI), such that the determining includes identifying structural paleo dissolution (SPD) voids in the fracture density index (FDI). Additionally, the operations include identifying a sweet spot for natural fractures in the naturally fractured carbonate reservoir using the three-dimensional structural paleo dissolution (SPD) model.

In some embodiments, the operations include obtaining a plurality of measurements from one or wells accessing the naturally fractured carbonate reservoir, and determining the reservoir parameters from the plurality of measurements. In some embodiments, the reservoir parameters include seismic attributes from seismic surveys of the subsurface geological structure. In some embodiments, the reservoir parameters include rock and mechanical properties from geological models of the subsurface geological structure. In some embodiments, the reservoir parameters include structural restoration models of the subsurface geological structure. In some embodiments, the reservoir parameters include rock geological characterizations of the subsurface geological structure. In some embodiments, the reservoir parameters include reservoir engineering measures obtained from production from the naturally fractured carbonate reservoir. In some embodiments, the operations include determining a geological model of the naturally fractured carbonate reservoir using the reservoir parameters, such that forming a natural fracture model by processing the obtained reservoir parameters includes using a plurality of petrophysical properties from the geological model. In some embodiments, the operations include controlling the drilling of a well in a subsurface geological structure to a location in the naturally fractured carbonate reservoir based on the identified sweet spot.

In another embodiment, a system for characterizing a naturally fractured carbonate reservoir is provided. The system includes a processor and a non-transitory computer-readable memory accessible by the processor and having executable code stored thereon. The executable code includes a set of instructions that causes the processor to perform operations that include obtaining a plurality of reservoir parameters representing a respectively plurality of properties of the naturally fractured carbonate reservoir and forming a natural fracture model by processing the obtained plurality of reservoir parameters to identify the presence and extent of natural fractures at locations in the naturally fractured carbonate reservoir. The operations also include determining, by the data processing system and using the discrete fracture network, a fracture density index (FDI), such that determining, using the discrete fracture network, a fracture density index (FDI) includes generating a raster map from the discrete fracture network, the raster map representing a fracture density per area. The operations further include obtaining a well log characterizing the naturally fractured carbonate reservoir, such that the well log includes a borehole image log, identifying structural paleo dissolution (SPD) indicators in the naturally fractured carbonate reservoir using the well log, and determining a three-dimensional structural paleo dissolution (SPD) model using the structural paleo dissolution (SPD) indicators and the fracture density index (FDI), such that the determining includes identifying structural paleo dissolution (SPD) voids in the fracture density index (FDI). Additionally, the operations include identifying a sweet spot for natural fractures in the naturally fractured carbonate reservoir using the three-dimensional structural paleo dissolution (SPD) model.

In some embodiments, the operations include obtaining a plurality of measurements from one or wells accessing the naturally fractured carbonate reservoir, and determining the reservoir parameters from the plurality of measurements. In some embodiments, the reservoir parameters include seismic attributes from seismic surveys of the subsurface geological structure. In some embodiments, the reservoir parameters include rock and mechanical properties from geological models of the subsurface geological structure. In some embodiments, the reservoir parameters include structural restoration models of the subsurface geological structure. In some embodiments, the reservoir parameters include rock geological characterizations of the subsurface geological structure. In some embodiments, the reservoir parameters include reservoir engineering measures obtained from production from the naturally fractured carbonate reservoir. In some embodiments, the operations include determining a geological model of the naturally fractured carbonate reservoir using the reservoir parameters, such that forming a natural fracture model by processing the obtained reservoir parameters includes using a plurality of petrophysical properties from the geological model. In some embodiments, the operations include controlling the drilling of a well in a subsurface geological structure to a location in the naturally fractured carbonate reservoir based on the identified sweet spot.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a block diagram of a process for characterizing the effects of structural paleo dissolution in a naturally fractured carbonate reservoir in accordance with an embodiment of the disclosure;

FIG. 2 depicts a porosity distribution within a 3D grid model in accordance with an embodiment of the disclosure;

FIG. 3 depicts a permeability distribution within a 3D grid model in accordance with an embodiment of the disclosure;

FIG. 4A depicts rose diagrams for various natural fractures: conductive fractures, mega fractures, partial conductive, bed bound fractures, resistive fractures 408, and partial resistive fractures in accordance with an embodiment of the disclosure;

FIG. 4B depicts a bore image interpretation using borehole logs in accordance with an embodiment of the disclosure;

FIG. 5 is an illustration of structural paleo dissolution forming voids controlled by different mechanical stratigraphy in accordance with an embodiment of the disclosure;

FIG. 6 is a portion of a borehole image log in accordance with an embodiment of the disclosure;

FIG. 7A depicts a stress diagram that illustrates probabilities of failure due to low mud weight conditions as indicated by the color legend and in accordance with an embodiment of the disclosure;

FIG. 7B is a portion of a borehole image log in accordance with an embodiment of the disclosure;

FIGS. 8A and 8B are flowcharts of a process for determining a discrete natural fracture distribution of a 3D fracture model in accordance with an embodiment of the disclosure;

FIG. 9 is a flowchart of a process for the determination of a 2D/3D geomechanics forward model in accordance with an embodiment of the disclosure;

FIG. 10A depicts a graph of normal stress v. normal displacement (Sn) in accordance with an embodiment of the disclosure;

FIG. 10B depicts a graph of dilation vs shear displacement (on), in accordance with an embodiment of the disclosure;

FIG. 11A depicts a stress diagram using normal stresses (61 and 03) in accordance with an embodiment of the disclosure;

FIG. 11B is a plot of shear stress vs normal stress and coefficient of friction in accordance with an embodiment of the disclosure;

FIGS. 12A-12D depict various properties shown on a 3D grid as determined from a scale up process to transform the fluid-flow planes into 3D grid block properties in accordance with an embodiment of the disclosure;

FIG. 13A depicts a 2D fracture network representing main fluid pathways in an area as input for a line density computation in accordance with an embodiment of the disclosure;

FIG. 13B depicts the resultant color-coded computed line density raster using the 2D fracture network of FIG. 13A in accordance with an embodiment of the disclosure;

FIG. 14 depicts a 3D grid model and portions of a borehole image log in accordance with an embodiment of the disclosure;

FIG. 15A depicts 3D structural paleo dissolution (SPD) voids associated with natural fractures (shown in orange) in a 3D model in accordance with an embodiment of the disclosure;

FIG. 15B depicts the structural paleo dissolution (SPD) voids distributed across the 3D model 1500 of a reservoir in accordance with an embodiment of the disclosure;

FIG. 16 is a block diagram of a workflow depicting multiple fracture realizations in accordance with an embodiment of the disclosure;

FIGS. 17A-17F depict various three-dimensional (3D) maps and overlays in accordance with an embodiment of the disclosure;

FIG. 18A is a plot of pressure and water cut vs. time that depicts the dynamic response in terms of pressure and watercut of a dual porosity/dual permeability scenario (matrix and fractures) in accordance with an embodiment of the disclosure;

FIG. 18B is a plot of pressure and water cut vs time that depicts the dynamic response in terms of pressure and watercut of a multiporosity scenario which considers fractures and the Structural Paleo Dissolution model (DPDP+SPD) in accordance with an embodiment of the disclosure; and

FIG. 19 is a block diagram of a data processing system in accordance with an embodiment of the disclosure.

### DETAILED DESCRIPTION

The present disclosure will be described more fully with reference to the accompanying drawings, which illustrate embodiments of the disclosure. This disclosure may, however, be embodied in many different forms and should not be construed as limited to the illustrated embodiments. Rather, these embodiments are provided so that this disclosure will be thorough and complete, and will fully convey the scope of the disclosure to those skilled in the art.

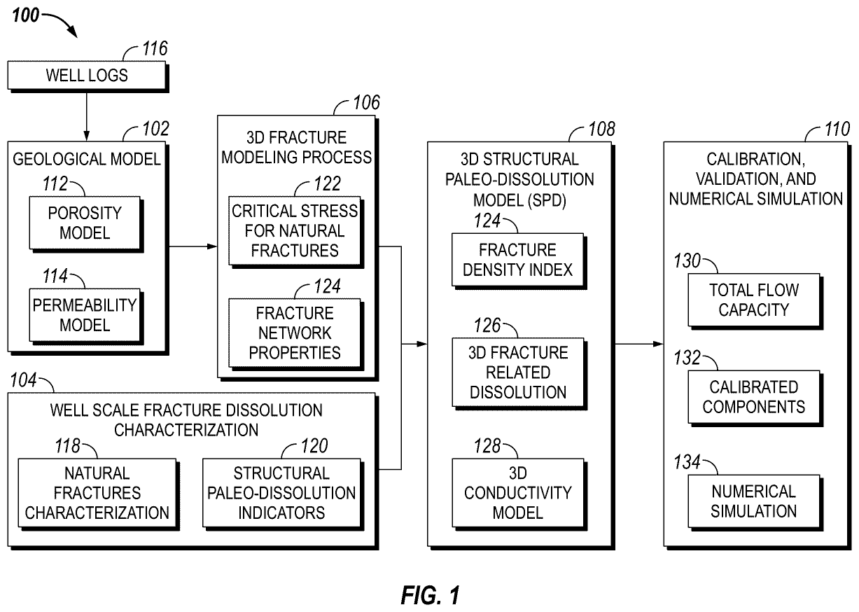

FIG. 1 depicts a process 100 for characterizing the effects of structural paleo dissolution in a naturally fractured carbonate reservoir in accordance with an embodiment of the disclosure. The process may include determining a geological model (block 102), determining a well scale fracture dissolution characterization (block 104), performing 3D fracture modeling (block 106), determining a 3D structural paleo dissolution model (block 108), and performing calibration, validation, and numerical simulation (block 110).

A geological model may be determined (block 102) using petrophysical characterization and modeling and rock properties, such as porosity, permeability, and petrophysical rock types. A structural framework for the geological model may be constructed using well tops information by spatial interpretation of the points using suitable software platforms, such as Petral manufactured by Schlumberger NV of Houston, TX, USA, or Gocad Mining Suite manufactured by Mira Geoscience of Westmount, Quebec, Canada. Process faults and layering may be added according to the reservoir internal depositional geometry. Additionally, the petrophysical properties can be extrapolated within a 3D grid model utilizing suitable geostatistic methods, such as kriging, Sequential Gaussian Simulation (SGS), or other suitable methods.

Determining the geological model (block 102) may include determining a porosity model (block 112) and determining a permeability model (block 114). Inputs to determination of the geological model may include measurements and properties from well logs (block 116). Such well logs may include borehole image logs, such as resistivity logs, sonics logs, or both. To determine the porosity model (block 112), petrophysical properties may be contained in the 3D grid of the geological model, and properties such as porosity or mineral volume can be used to interpolate (for example, via cokriging) the elastic properties and rock strength properties into the 3D model. The correlations established between the dynamic and static mechanical properties may thus be preserved in relation with the petrophysical properties.

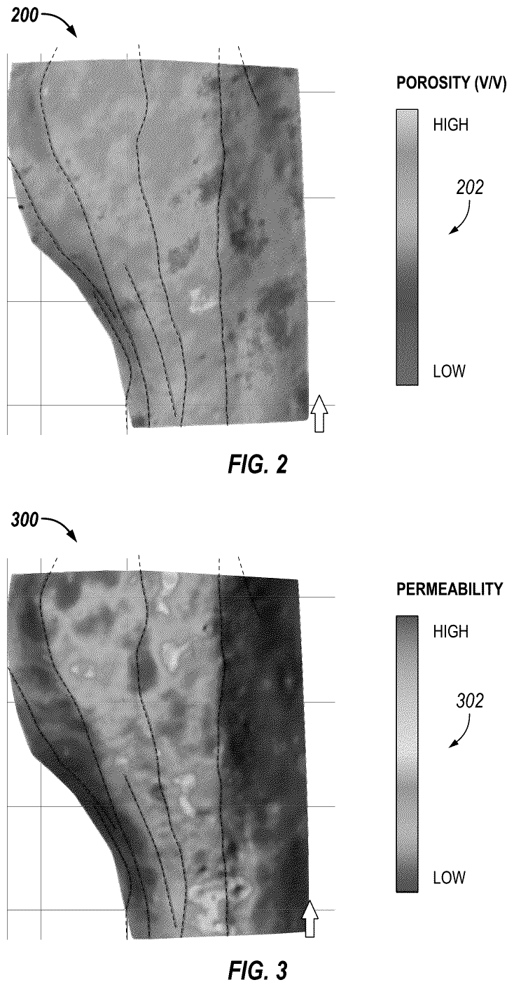

Porosity may be calculated from conventional wireline logs such as bulk density, gamma ray, and neutron porosity and, in some embodiments, core-plug measurements, all integrated inside a petrophysical workflow. The porosity may be extrapolated into a 3D grid model using a cokriging algorithm following by an additional or secondary property such as acoustic impedance extracted from seismic volume cube, facies or other type of guides. An example of this technique is described in Mojeddifar, S., Kamali, G. & Ranjbar, H. (2015), “Porosity prediction seismic inversion of a similarity attribute based on a pseudo-forward equation (PFE): a case study from the North Sea Basin, Netherlands,” Pet. Sci. 12, 428-442. By way of example, FIG. 2 depicts a porosity distribution within a 3D grid model 200 in accordance with an embodiment of the disclosure. As shown in FIG. 2, the porosity (in volume of space divided by total rock volume (v/v)) is shown in different colors indicated by the color legend 202.

As mentioned supra, determining the geological model may also include determining a permeability model (block 114). To determine the permeability model, matrix permeability (K_{Facim}=K_{Matrix}) may be calculated and modeled from petrophysics workflows by reconciling core data to wireline log data. The matrix permeability may be modeled into a 3D geo-cellular grid using algorithms for co-correlations. By way of example, FIG. 3 depicts a permeability distribution within a 3D grid model 300 in accordance with an embodiment of the disclosure. As shown in FIG. 2, the permeability is shown in different colors indicated by the color legend 302.

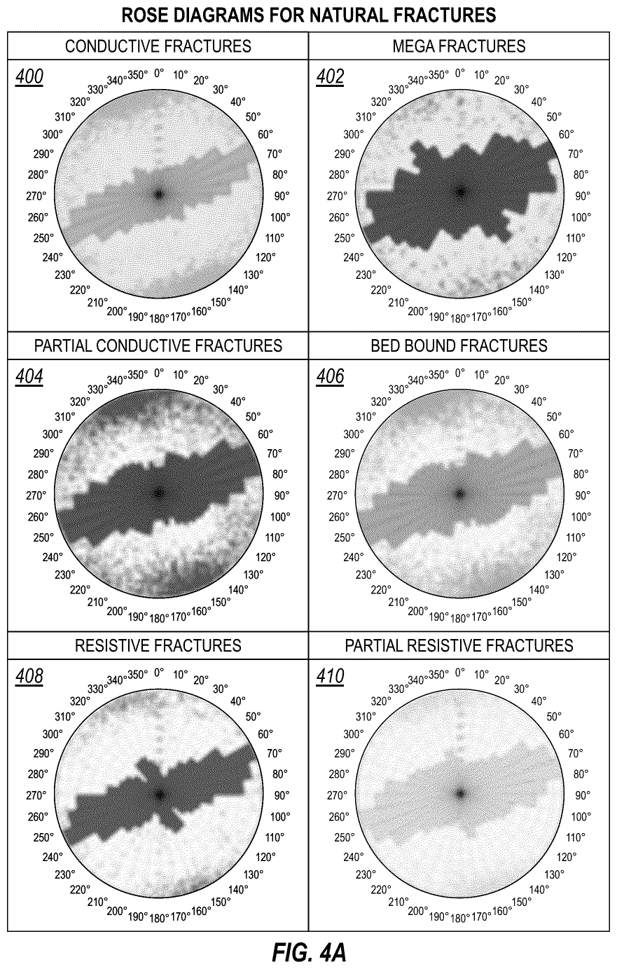

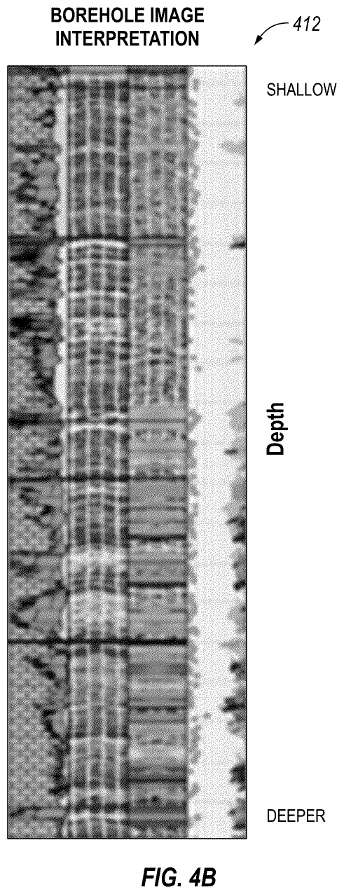

As shown in FIG. 1, determining a well scale fracture dissolution characterization (block 104) may include a natural fractures characterization (block 118) and determining structural paleo dissolution indicators (block 120). To determine the natural fractures characterization (block 118), borehole resistive or sonic image logs may be used to obtain natural fractures attributes, such as fracture type, dip angle, dip azimuth and intensity at well level. Additionally, the apparent aperture may be estimated through microresistivity borehole imaging techniques, such as described in S. M. Luthi and P. Souhaité, (1990), “Fracture apertures from electrical borehole scans,” GEOPHYSICS 55:821-833. The apparent fracture aperture may be calibrated using core plug measurements at reservoir conditions. In some embodiments, the categories of fractures identified may include dominantly conductive and partially conductive, interpreted to be open fractures. By way of example, FIG. 4A depicts rose diagrams for various natural fractures: conductive fractures 400, mega fractures 402, partial conductive 404, bed bound fractures 406, resistive fractures 408, and partial resistive fractures 410 in accordance with an embodiment of the disclosure. In a further example, FIG. 4B depicts a bore image interpretation using borehole logs 412, in accordance with an embodiment of the disclosure.

Additionally, determining the well scale fracture dissolution characterization (block 104) includes determining structural paleo dissolution indicators (block 120). The initiation and propagation of natural fractures are mostly controlled by mechanical stratigraphy, in-situ stress, and paleo-deformation events. Localized cavities observed frequently in carbonate rocks occur preferentially along natural fractures, which act as main conduits for paleo-fluids promoting chemical dissolution processes. As such, a strong relationship exists between mechanical stratigraphy and the initiation of cavities and has been confirmed by outcrop studies in different carbonate basins. In those analogues, brittle, low-porosity units with high fracture density distribute paleofluids homogeneously, restricting localized dissolution. By contrast, thick, ductile, and highly-porous stratigraphic units allowed paleofluids to flow and localize the dissolution process along large, widely spaced fracture swarms, promoting the initiation and growth of cavities. For example, FIG. 5 is an outcrop illustration 500 of structural paleo dissolution forming voids controlled by different mechanical stratigraphy in accordance with an embodiment of the disclosure. FIG. 5 illustrates the typical geometry and localization fracture-related cavities, with arrows (in red) depicting conceptual flow pathways suggested by the observations and outcrop measurements.

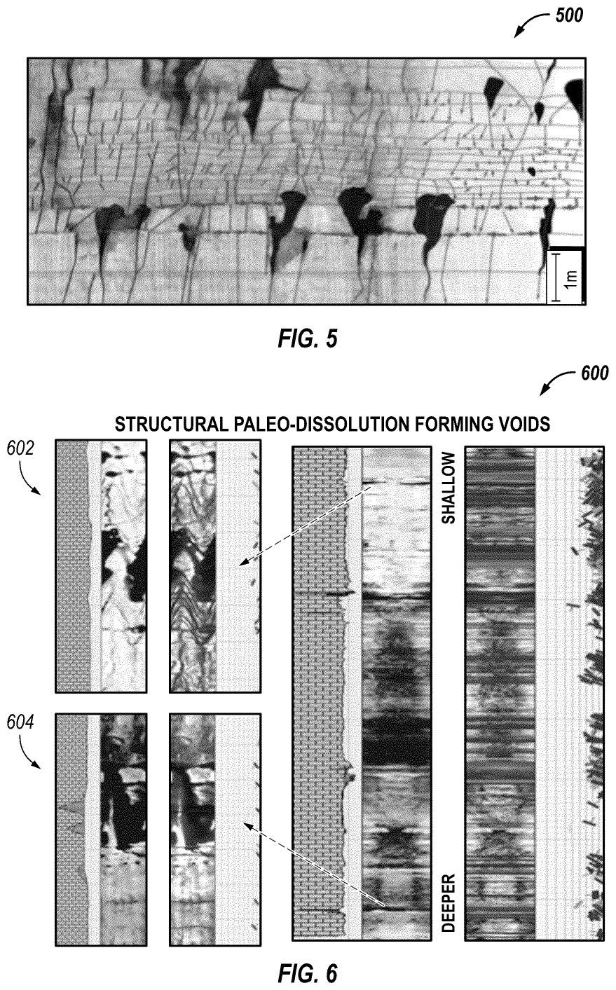

Similarly, in subsurface carbonate rocks, voids or cavities development and localization obey the structural paleo dissolution processes, occurring preferentially in fractured intervals that imprint vertical permeability within reservoir hydraulic units and are controlled by mechanical stratigraphy. Cavities-prone units may be partially identified by borehole image logs and reservoir dynamic data, such as pressure transient analysis or production log tests. The combination of these information may be used to validate the structural paleo dissolution model. By way of example, FIG. 6 depicts a portion 600 of a borehole image log in accordance with an embodiment of the disclosure. The borehole image log portion 600 shows structural paleo dissolution forming voids and proto cavities, as shown in breakouts 602 and 604.

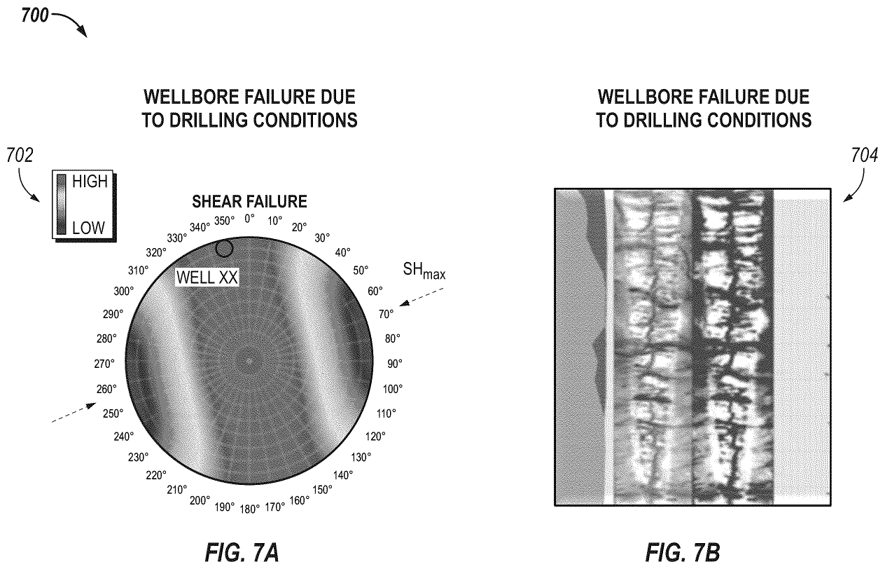

Additionally, identifying structural paleo dissolution indicators may include a well-scale geomechanical model in order to evaluate wellbore failure through the formation of washouts or breakouts, potentially impacting the quality of the image log interpretation. Such detailed wellbore failure geometry analysis and geomechanics in the workflow prevents misinterpreting wellbore failure geometries by structural paleo dissolution voids (diagenetic in nature), as borehole image signature of breakouts and cavities are sometimes alike. For example, FIG. 7A depicts a stress diagram 700 that depicts probabilities of failure due to low mud weight conditions as indicated by the color legend 702 and in accordance with an embodiment of the disclosure. FIG. 7B depicts portion 704 of a borehole image log in accordance with an embodiment of the disclosure. As shown in these figures, wellbore failure due to low mud weight conditions may generate additional features that correspond to specific drilling conditions rather than structural paleo dissolution processes.

As shown in FIG. 1, the process 100 may also include performing 3D fracture modeling (block 106). The 3D fracture modeling includes fracture characterization, deformation model and in-situ stress model in order to build a robust fracture model. The 3D fracture modeling may include determining the critical stress for natural fractures (block 122) and determining fracture network properties (block 124).

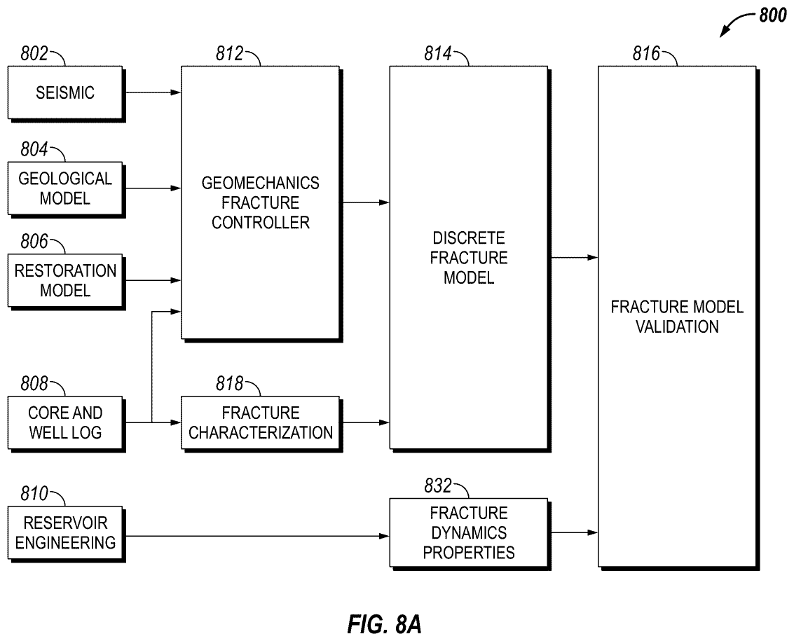

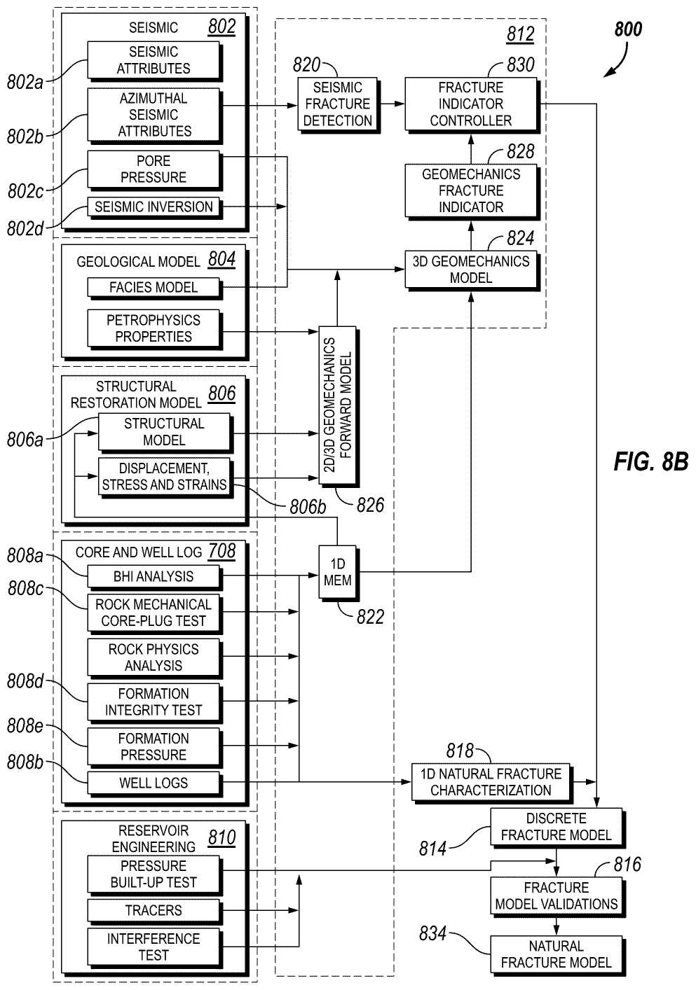

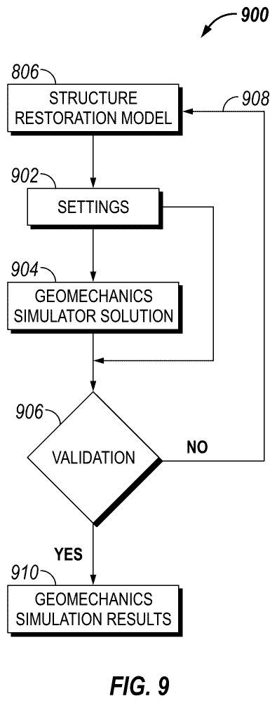

In some embodiments, the determination of a 3D fracture model may be performed according to the techniques described in U.S. Pat. No. 10,607,043 filed Sep. 14, 2017, and titled “SUBSURFACE RESERVOIR MODEL WITH 3D NATURAL FRACTURES PREDICTION,” a copy of which is incorporated by reference in its entirety. The determination of the 3D fracture model is further illustrated in FIGS. 8A-8B and 9 and discussed supra.

FIGS. 8A and 8B depicts a process 800 for determining a natural fracture distribution of a 3D fracture model in accordance with an embodiment of the disclosure. The inputs to the process 800 may include different reservoir parameters and properties obtained via different techniques and known earth science. As shown in FIGS. 8A and 8B, such inputs may include seismic attributes from seismic surveys (802); rock and mechanical properties from geological modeling (804); measures from structural restoration models (806); core and well logs (808) obtained from formation core samples and well logs performed in wellbores drilling into a reservoir; and reservoir engineering measures obtained (810) from production measures and reservoir simulations of a reservoir layer.

The process 800 may include a geomechanics fracture controller (812), determining a discrete fracture model (814), and validating the fracture model (816). The geomechanics fracture controller (812) may integrate the paleo-stress from structural restoration model (806) obtained for several stages in geological time, and current stress regime conditions obtained through a geomechanical numerical simulation model. In some embodiments, geomechanics fracture controller (812) may apply seismic volume interpretation techniques and attributes to detect possible faults and natural fractures alignments by using post stack discontinuities attributes, azimuthal analysis, and elastic seismic inversion.

The determination of the natural fracture model (814) may include quantifying fracture density in the subsurface reservoir layer using the output from the geomechanics fracture controller (812), and a 1D fracture characterization (818) provided from core samples and borehole well log images from a borehole image (BHI) analysis process 808a (shown in FIG. 8B). The determination of the natural fracture model (814) also includes the determination of fracture dimensions and their properties into the discrete fracture model, described in the disclosure. Examples of the fracture properties resulting from the determination of the natural fracture model (814) include fracture position, orientation, geometry, porosity, aperture, permeability, and the like. In other embodiments, other fracture properties may also be estimated during the determination of the natural fracture model (814).

The validation of the fracture model (816) may include cross-checking or validating the model using reservoir production data. In some embodiments, the natural fracture model may be upscaled to conform to a fine-scale cell grid of geological model and reproduce the natural fracture distribution and their properties, for comparison with the reservoir production data for validation proposes. Several types of reservoir production data can be used to calibrate the fracture models with reservoir engineering data. Examples of such reservoir production data are results of measures obtained from: PTA (Pressure Transient Analysis), tracers, drilling operation events, PLT (production logs), and the like. In other embodiments, other reservoir production data can also be used for cross-checking during the validation of the fracture model (816).

FIG. 8B depicts aspects of the geomechanics fracture controller (812) in further detail in accordance with an embodiment of the disclosure. As shown in FIG. 8B, a seismic fracture detection process (820) is provided with seismic attributes (808A) obtained from seismic volume results (802). The seismic attributes (808A) may include attributes related to natural fractures detections or dislocation detections. Examples of such attributes obtained from the seismic dislocations attribute analysis results may include: variance, anti-tracking, flatness, curvature, and the like. In other embodiments, other seismic attributes may also be provided. As will be appreciated, seismic fracture attributes may be unable to be compared straight forward at wellbore scale due to resolutions issues. However, seismic attributes may be used as a seismic fracture controller or conduct for minor fractures detected at wellbore scale if the relations regarding to the locations and intensity between them exist.

As shown in FIG. 8B, advance seismic fracture detection may also be performed during the seismic fracture detection process (820) using azimuthal seismic analysis (808B) to capture the variations of the wave propagation at different directions. Such variations in wave propagation form anisotropic volumes in the reservoir layer and are helpful in detecting fractures. This azimuthal analysis may be based on whether the anisotropy response in the reservoir is due to natural fractures or caused by another reason. In order to identify whether the anisotropy response may be azimuthal shear anisotropy, sonic acoustic acquisition may be performed at a well location in the naturally fractured reservoir. An example of azimuthal seismic analysis is described in: Gray, F. D. and Head, K. J., 8000, Fracture Detection in the Manderson Field: A 3D AVAZ Case History: The Leading Edge, Vol. 19, No. 11, 1814-1281; and Khalid Al-Hawas, Mohammed Ameen, Mohammad Wahab, and Ed Nebrija, Saudi Aramco, Dhahran, Saudi Arabia Colin Macbeth, Heriot-Watt University, Edinburgh, U.K., 8003, “Delineation of Fracture Anisotropy Signatures in Wudayhi Field by azimuthal seismic data”, the Leading Edge.

The geomechanics fracture controller (812) may include a determination of a 1D mechanical earth model (MEM) (822) to determine the rock mechanical properties and stress regime conditions in the reservoir layer. The determination of the 1D MEM may include computing the elastic rock mechanical properties deriving from well logs (808b) and rock mechanical test (808c); using additional information such as reservoir formation pressures (808e) and a Formation Integrity Test (FIT) (808d), the in situ stress regime can be predicted and mechanical stratigraphy (Geomechanical Facies) computed. The mechanical stratigraphy may conform the rock mechanical response to the geological deformation process and may be used as constraints for natural fractures presence, constraining their development to some particular layer through brittleness concepts, depending also on the deformation magnitude. Additionally, the maximum horizontal stress direction may be detected by the Borehole Image Analysis (BHI) (808a), and the in situ stress magnitude derived from the 1D MEM may be used to predict the stress regime of a 3D geomechanics model (824) (also referred to as a “3D mechanical earth model (MEM)”).

As shown in FIG. 8B, the geomechanics fracture controller (812) may include the determination of 2D/3D geomechanics forward model (826) that combines a structural model (808a) and displacement, paleo-stress, and strain measures 808b from the structural restoration model (808) with petrophysical properties (804b) from geological model (804). The results take the form of structural restoration as horizons displacement and deformation using boundary conditions. The determination of 2D/3D geomechanics forward model (826) may include as a Finite Element Method (FEM) using geomechanics numerical simulation software, to estimate the tensor stress regime corresponding to the deformation estimate from structural restoration at the in situ stress conditions.

FIG. 9 depicts a process 900 of the determination of 2D/3D geomechanics forward model (826) in accordance with an embodiment of the disclosure. The initial parameter and strain boundary conditions may be defined for the numerical simulation and processing may be iteratively repeated until an equilibrium stress is obtained according to present to in situ stress conditions in the reservoir. As will be appreciated, a number of geomechanics simulator methodologies are commercially available and are able to estimate stress conditions using the deformation model from the structural restoration model. These results can be used to calculated or predict the possible origin for the natural fractures as stretching zones, compression zones which is an input to classify the different kind of natural fractures and their possible orientations from a qualitative perspective, using a strain tensor derivate from the 2D/3D geomechanics forward model (826). Example geomechanics simulator methodologies include ABAQUS™ from Dassault Systemes; VISAGE™ from Schlumberger; and ELFEN™ from Rockfield, COMSOL™ from AltaSim Technologies.

As shown in FIG. 9, input measures from the structural restoration modeling (806) are received for the 2D/3D geomechanics forward model (826) and stored as initial settings (902). The settings (902) are then processed by a geomechanics simulator (904) of the type described supra. The output from the geomechanics simulator is then cross-checked or validated (906) against specified stress equilibrium conditions. As shown in FIG. 6, if confirmation results are not achieved during the current iteration (line 908), the previous settings of the step are adjusted for iteration by simulation step. The iterations may be repeated until specified conditions are validated. After validation, the simulation results (910) may be provided as the 2D/3D geomechanics forward model (826) and may indicate conditions of stress, strain and pre-existing faults and fractures in the reservoir layer.

The 3D geomechanics model (824) of the geomechanics fracture controller (812) may include the measures and indications of rock mechanical properties distribution. The 3D geomechanics model (824) may further include elastic rock properties and rock strength throughout the 3D geological grid. The 3D geomechanics model (824) may be calculated by boundary conditions to simulate the in situ stress regime. As discussed in the disclosure, the in situ stress regime is a condition where the stress field is unperturbed or is in equilibrium without any production or influences of perforated wells.

The determination of the 3D geomechanics model (824) may use elastic seismic inversion (802d) in the form of acoustic impedance, bulk density, and may also include pore pressure (802c) covering the 3D geological model area. The seismic inversion parameters may be obtained from an elastic seismic inversion (802d) and seismic velocity analysis for the pore pressure (802c). The determination of the 3D geomechanics model (824) may also be based on rock mechanical correlations between dynamics and static elastic rock mechanical properties which have been determined as a result of the 1D mechanical earth model (MEM) (822). 3D mechanical stratigraphy may also be calculated using the elastic properties of the 3D geomechanics model (824), and may be used to constrain the fracture distribution using brittleness property definition. An example processing methodology for determining the 3D geomechanics model (824) is described in: Herwanger, J. and Koutsabeloulis, N. C.: “Seismic Geomechanics—How to Build and Calibrate Geomechanical Models using 3D and 4D Seismic Data”, 1 Edn., EAGE Publications b.v., Houten, 181 pp., 8011.

Additionally, geomechanics forward modeling of the type described infra and shown in FIG. 9 may be used as a loop process between the 2D/3D geomechanics forward model (826) and 3D geomechanics model (824). Such a loop process may capture the displacement and deformation quantified in the structural restoration model (806), and may provide more accurate calculations of the strain distribution corresponding to the structural evolution faulting and folding in the model (806).

The determination of the 3D geomechanics model (826) may include a geomechanics fracture indicator (828) that may form indications of fractures based on selected rock mechanical properties distributed for the 3D geomechanics model (824). The mechanical stratigraphy may be defined in the 3D geomechanics model (824) by using the Brittleness concept and may be used as a geomechanics fracture indicator to define the fracture position and density or spacing through the layering. A strain or plastic strain model may be determined in the 2D/3D geomechanics forward model (826) and 3D geomechanics model (824) and may be used as indicator of fracture orientation (dip and azimuth) and possible areal/volumetric density distribution, according to the kind of geological structural environment. Several components of fractures can be considered as geomechanics indicator for fractures, such as fractures relate to folding and fractures related to faulting. The quantifications about the strain may be qualitative in terms of real fracture density present in the reservoir.

As shown in FIG. 8B, the determination of the 3D geomechanics model (824) may include a fracture indicator controller (830). The fracture indicator controller (830) may compare attributes determined from seismic fracture detection (820) and geomechanics fracture indicator (828) in terms of fracture position, fracture density and orientation in a qualitative way, to evaluate possible coincidence zones, between the models, where natural fractures can be expected to be created. In some cases, the attributes determined from seismic fracture detection (820) and geomechanics fracture indicator (828) may be complementary due to the different vertical and areal resolution in which both of them are calculated.

The discrete fracture model (814) may be determined subsequent to identification of natural fracture locations by the fracture indicator controller (290). The discrete fracture model may build a representative natural fracture model based on stochastic mathematical simulations. As shown in FIG. 8B, the discrete fracture model (814) may be constructed from the fracture indicator controller (290) and the intensity and orientation from the 1D natural fracture characterization (818).

The determination of the discrete fracture model (814) may receive as input the results of the 1D natural fracture characterization (818), which may be obtained from the borehole image resistivity analysis or acoustic image interpretation (808a) of the core and well logs (808) and may represent the intensity fracture, aperture, fracture classification and fracture orientation along a wellbore.

As noted infra, the discrete fracture model (814) may be determined using the fracture indicator controller (830) and the 1D natural fracture characterization (818). The determination may constrain the orientation and fracture intensity in a qualitative way, and using the 1D natural fracture characterization (818), may calculate the real fracture intensity quantification. This output can be used to predict a natural fracture model through the discrete fracture network methodology. For fracture intensity quantification purposes, the fracture intensity derived from the fracture indicator controller (830) may be normalized for comparison with the BHI fracture intensity derived from the 1D natural fracture characterization (818).

The fracture model validation 816 may validate the discrete fracture model (814). The validation may be performed using reservoir production data. As shown in FIG. 8A, several types of data may be used as fracture dynamic properties (832) to calibrate the fracture model with reservoir engineering measures (810). For example, results from a PTA (Pressure Transient Analysis) test, or measures from tracers, drilling operations, production logs, and the like may be used. For example, pressure transient analysis can estimate permeability contribution due to fracture presence and the capacity for fluid flow due to the fracture presence. In another example, tracer injection, production logs, interference test and possibly some drilling events as can indicate mud loss circulation that can provide evidence of the presence of natural fractures. The discrete fracture model (814) may upscale into the fine-scale cell grid geological model, and reproduce the natural fracture distribution and their properties to compare with the validation data.

After the fracture model validation, a discrete natural fracture model (834) may be produced as a result of the process 800. As previously described, the discrete natural fracture model (834) may indicate the presence and extent of natural fractures in the subsurface geological structures (for example, a naturally fractured carbonate reservoir).

In order to determine the critical stress for natural fractures (block 122), the stress regime predicted for the 3D grid model may be used to apply the Coulomb failure criteria for the fracture planes, resulting in the differentiation of hydraulically conductive fractures from non-hydraulically conductive fractures based on their optimal orientation with respect to the current in-situ stress. As will be appreciated, non-permeable fractures are those outside the critically stressed orientation domain.

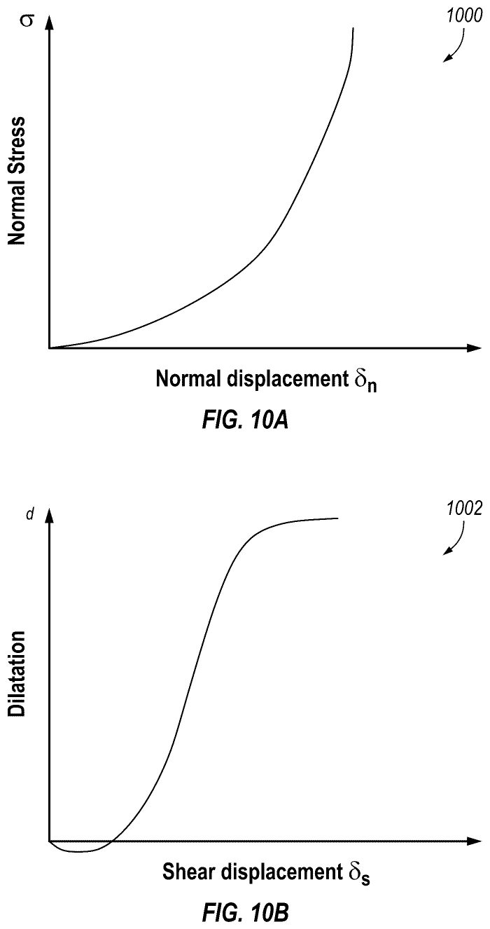

The fracture aperture may be based on normal closure and shearing dilatation. For example, FIG. 10A depicts a graph 1000 of normal stress v. normal displacement (δₙ), and FIG. 10B depicts a graph 1002 of dilation vs shear displacement (δₙ), in accordance with an embodiment of the disclosure. As only the near-critically-oriented fractures can dilate, shear dilation occurs only partially, while the other fractures are still without dilation. The stress-dependent permeability for fractures that incorporates the effects of both normal closure and shear dilation may be modeled according to the techniques described in Ki-Bok Min et al., (2004), “Stress-dependent permeability of fractured rock masses: a numerical study,” International Journal of Rock Mechanics and Mining Sciences, Volume 41, Issue 7, Pages 1191-1210.

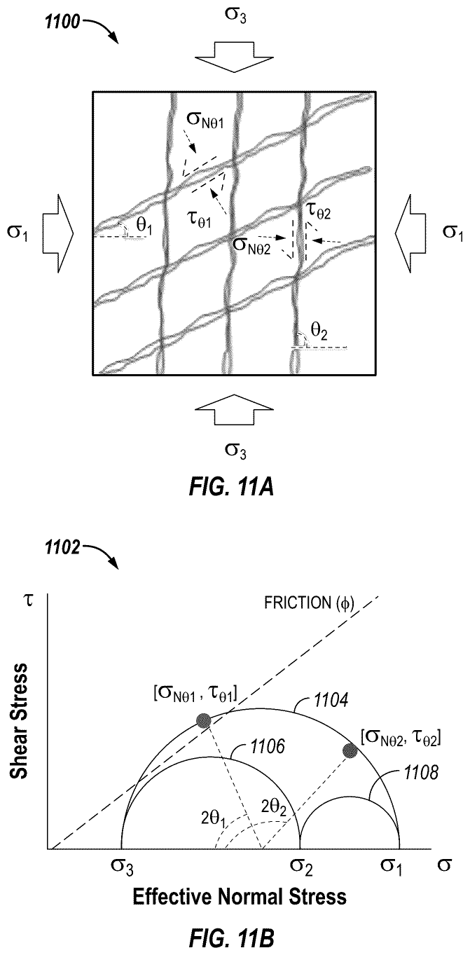

FIGS. 11A and 11B depict nonlinear behavior for fracture apertures under effective normal stress. FIG. 11A depicts a stress diagram 1100 using normal stresses (01 and 03) in accordance with an embodiment of the disclosure. FIG. 11B is a plot 1102 of shear stress vs normal stress and coefficient of friction and depicts a Mohr diagram in accordance with an embodiment of the disclosure. FIG. 11B illustrates “Mohr circles” 1104, 1106, and 1108, as is known in the art.

The equivalent aperture of normal closure and shear dilation may be formulated based on the following empirical equation:

$$\begin{matrix}Permeability \\ in fracture rock masses\end{matrix} \approx \begin{matrix}Permability \\ from normal closure\end{matrix} + \begin{matrix}Permeability \\ from shear dilation\end{matrix} \qquad ( 1 )$$

Using the determined aperture distribution, a standard cubic law function may be used as an equation for the stress-dependent permeability to incorporate the effects of both normal closure and shear dilation of fractures through the aperture distribution based on critical stress.

As also shown in FIG. 1, performing 3D fracture modeling (block 106) includes determining fracture network properties (block 124). Fracture networks typically serve as the major fluid-flow paths for fluid transportation within subsurface rocks, especially if the matrix permeability is low compared to the permeability of the fracture. The partitioning of fluid-flow within a population of fractures relies on the spatial connectivity of fracture geometry and the transmissivity of individual fractures. Both may be affected by the geomechanical conditions.

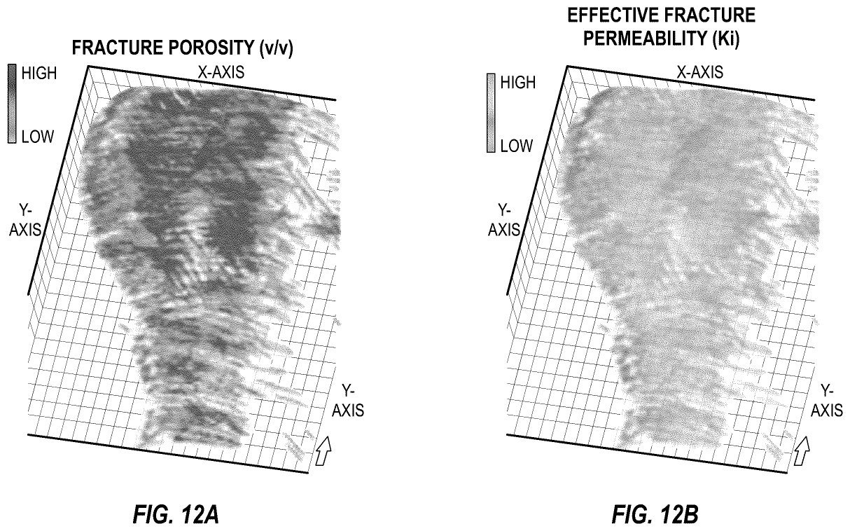

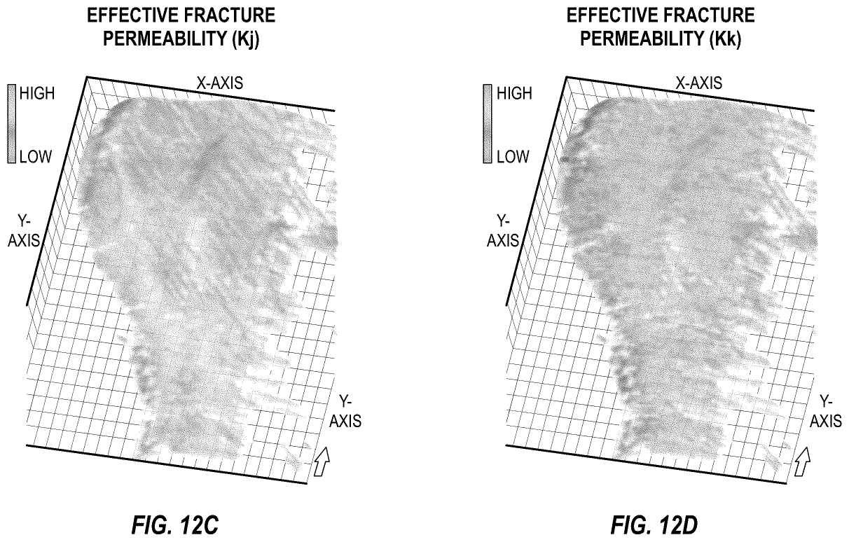

Determining fracture network properties may using a scale-up process to transform the fluid-flow planes into 3D grid block properties (for example, porosity and permeability) that generate fracture tensor permeability, porosity and sigma or shape factor. By way of example, FIGS. 12A-12D depict various properties shown on a 3D grid as determined from this scale up process in accordance with an embodiment of the disclosure. FIG. 12A depicts fracture porosity (v/v), FIG. 12B depicts effective fracture permeability, FIG. 12C depicts effective fracture permeability, and FIG. 12D depicts effective fracture permeability. In some embodiments, the conversion from discrete fracture planes to a grid model may be performed using Oda's method. In some embodiments, the conversion from discrete fracture plans to a grid model may be performed according to the techniques described in U.S. Publication No. 2020/0095858 filed Nov. 26, 2019, and titled “MODELING RESERVOIR PERMEABILITY THROUGH ESTIMATING NATURAL FRACTURE DISTRIBUTION AND PROPERTIES,” a copy of which is incorporated by reference in its entirety. In such embodiments, the upscaling process may be performed using a software package such as Petrel™, Fracflow®, or other suitable upscaling methodology.

As mentioned supra, the process 100 includes determining a 3D structural paleo dissolution model (block 108) using the outputs from the well scale fracture dissolution characterization (block 104) and the 3D fracture modeling process (block 106). The 3D structural paleo dissolution model may represent the voids formed by structural paleo dissolution processes by combining the associated fractures-voids described in the well scale fracture dissolution characterization and the fracture network through the fracture density index (FDI) model. Once the fracture model has been constructed and the structural paleo dissolution voids characterized at well scale, a combination between these two components will result in the 3D structural paleo dissolution model. The model adheres to the known process of a fracture network acting as the main paleo structural flow pathway driving carbonate dissolution, with mechanical stratigraphy controlling vertical distribution of the dissolution features occurrences.

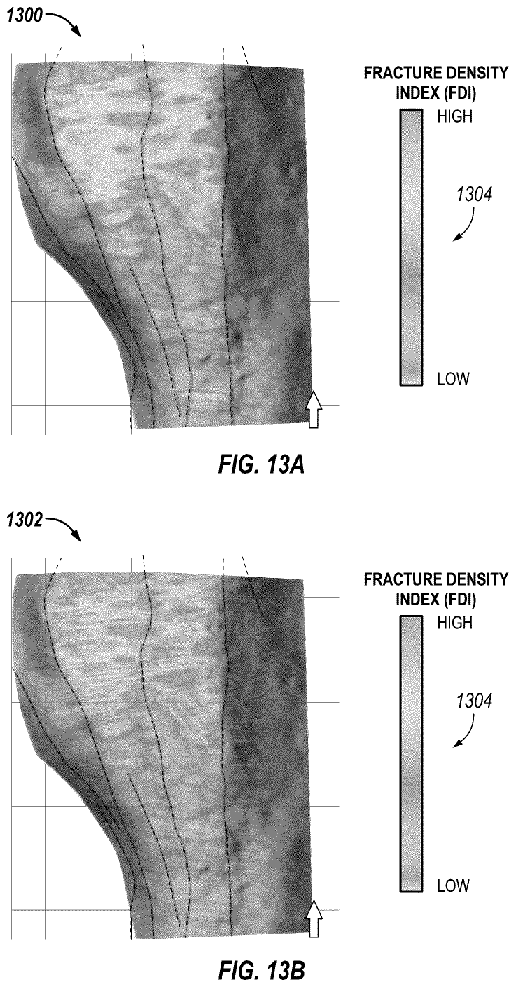

As shown in FIG. 1, determining a 3D structural paleo dissolution model (block 108) includes determining a fracture density index (block 124), determining a 3D fracture related dissolution (block 126), and determining a 3D conductivity model (block 128). The fracture density index represents critically stressed fluid pathways and may be determined by converting into two-dimensional (2D) lines to compute a continuous fracture density property. For example, various geographic information systems (GIS) geoprocessing software may have tools for computing line density. In some embodiments, the conversion of the 3D discrete fracture map to 2D lines may be performed by ArcGIS available from Environmental Systems Research Institute (Ersi), California, USA. In such embodiments, a raster map representing fracture density per area may be generated. Additionally, a suitable color-indexed palette may be assigned to enable visual identification of areas where natural fractures are more concentrated. For example, FIG. 13A depicts a 2D fracture network 1300 representing main fluid pathways in an area as input for a line density computation in accordance with an embodiment of the disclosure. FIG. 13B depicts the resultant color-coded computed line density raster 1302 using the 2D fracture network of FIG. 13A, as indicated by the legend 1304, in accordance with an embodiment of the disclosure.

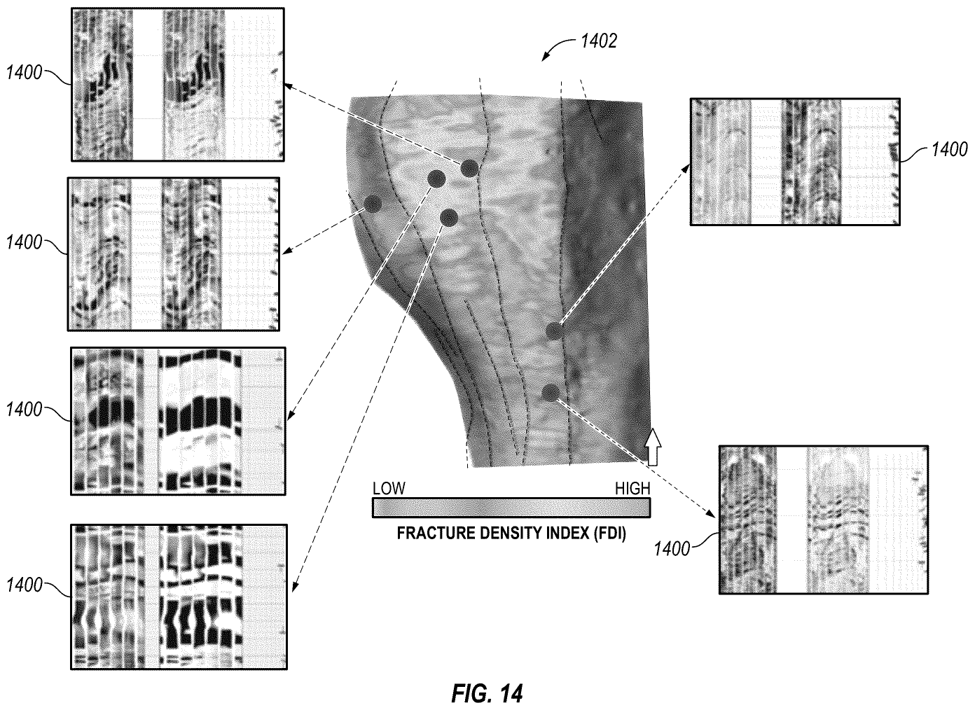

Determining a 3D structural paleo dissolution model (block 108) also includes determining a 3D fracture related dissolution (block 126). Determining a 3D fracture related dissolution may be performed by extracting the fracture-related voids from borehole image log interpretation by sampling different regions of the fracture density index model to give a representative areal distribution of these features across the reservoir. For example, FIG. 14 depicts the extraction of fracture-related voids from borehole image log portions 1400 in accordance with an embodiment of the disclosure. As shown in FIG. 14, the fracture-related voids due to structural paleo dissolution (SPD) processes (shown in blue) and natural fractures (shown in red) in the fracture density index model 1402 may be identified. The association between the high density of hydraulically permeable fractures and the incidence of dissolution voids may enable determination of the structural paleo dissolution (SPD) trends using the fracture density index (FDI).

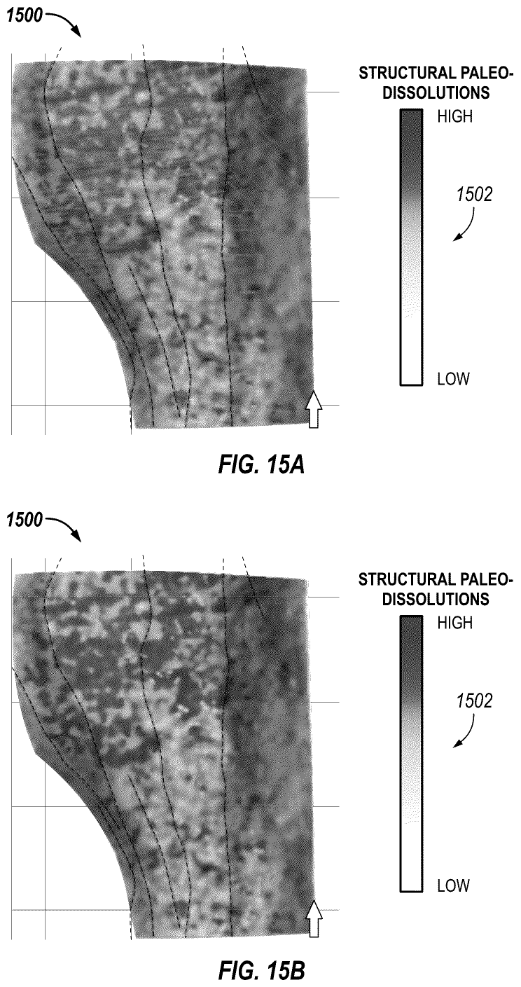

Additionally, as shown in FIG. 1, determining a 3D structural paleo dissolution model (block 108) includes determining a 3D conductivity model (block 128). To determine the 3D conductivity model, structural paleo dissolution (SPD) voids may be distributed following the pattern of the fracture density index model and the observation points from borehole image log, By way of example, FIG. 15A depicts 3D structural paleo dissolution (SPD) voids associated with natural fractures (shown in orange) in a 3D model 1500 in accordance with an embodiment of the disclosure. FIG. 15B depicts the structural paleo dissolution (SPD) voids 1500 distributed across the 3D model 1500 of a reservoir in accordance with an embodiment of the disclosure. As shown in FIGS. 15A and 15B and the legend 1502, the map displaying brown-coded colors represent the spatial distribution of structural paleo dissolution (SPD) zones, where dark brown colors indicate high incidences of structural paleo dissolution (SPD), and light brown colors represent low incidences of structural paleo dissolution (SPD).

As shown in FIG. 1, the process 100 includes performing calibration, validation, and numerical simulation (block 110) using the output from the 3D structure paleo dissolution (SPD) model (block 108). The calibration, validation, and numerical simulation may connect the three components characterizing a reservoir: rock matrix, natural fractures, and structure paleo dissolution (SPD) spaces to produce a reliable and consistent status model. The calibration, validation, and numerical simulation (block 110) may include determining total flow capacity (block 130), determining calibrated components (block 132), and performing a numerical simulation (block 134).

To determine total flow capacity, the equivalent permeability for the three components (that is, rock matrix, natural fractures, and structure paleo dissolution (SPD) spaces) may be determined according to the hierarchy described in U.S. Publication No. 2020/0095858 filed Nov. 26, 2019, and titled “MODELING RESERVOIR PERMEABILITY THROUGH ESTIMATING NATURAL FRACTURE DISTRIBUTION AND PROPERTIES,” a copy of which is incorporated by reference in its entirety, in which the fractures have the major impact for the fluid flow movement, followed by structural paleo dissolutions (SPD), and lastly rock matrix. Using this hierarchy, the flow capacity may be calculated for each component and optimized using reservoir dynamic response, as shown in the following Equation:

$$\begin{matrix}Total Flow \\ Capacity from \\ Well test ( {KH}_{PTA} )\end{matrix} \approx \begin{matrix}Flow Capacity for \\ Matrix ( {KH}_{FFacim} )\end{matrix} + \begin{matrix}Flow Capacity for \\ Fracture \\ ( {KH}_{Frac \_ simulate} )\end{matrix} + \begin{matrix}Flow Capacity for \\ SPD ( {KH}_{SPD} )\end{matrix}$$

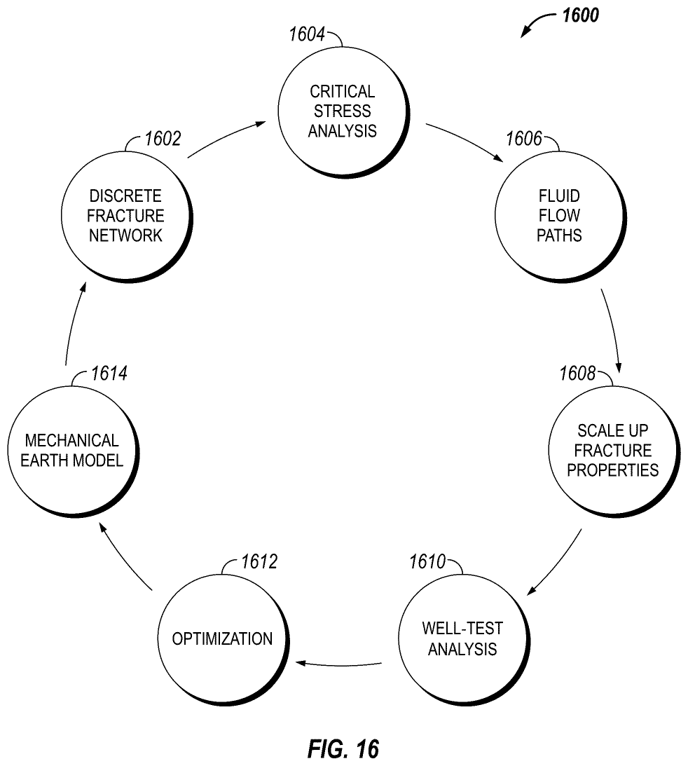

From the previous steps of the process 100, the discrete fracture network is upscaled from the three-dimensional (3D) object planes space to the geocellular gridded model. This process generates fracture porosity distribution, transfer functions coefficient and fracture permeability. The effective permeability tensor (Kᵢ,Kⱼ,Kₖ) is used to calculate (KH_{Fract-simulate}), then multiple realizations are constructed based on the workflow 1600 depicted in FIG. 16. As shown in FIG. 16, the workflow 1600 depicts multiple fracture realizations that may be used for validations and calibrations in accordance with an embodiment of the disclosure. The impact of critically stressed aperture and permeability on fluid flow may be quantified using equivalent permeability, which considers fracture, HPS, and matrix flow and the interaction between these three factors. For example, FIG. 16 depicts the following determinations: discrete fracture network 1602, critical stress analysis 1604, fluid flow paths 1606, the scale up of fracture properties 1608, well test analysis 1610, optimization 1612, and a mechanical earth model 1614. As discussed infra, the realizations may be determined according to the techniques described in U.S. Publication No. 2020/0095858 filed Nov. 26, 2019, and titled “MODELING RESERVOIR PERMEABILITY THROUGH ESTIMATING NATURAL FRACTURE DISTRIBUTION AND PROPERTIES.

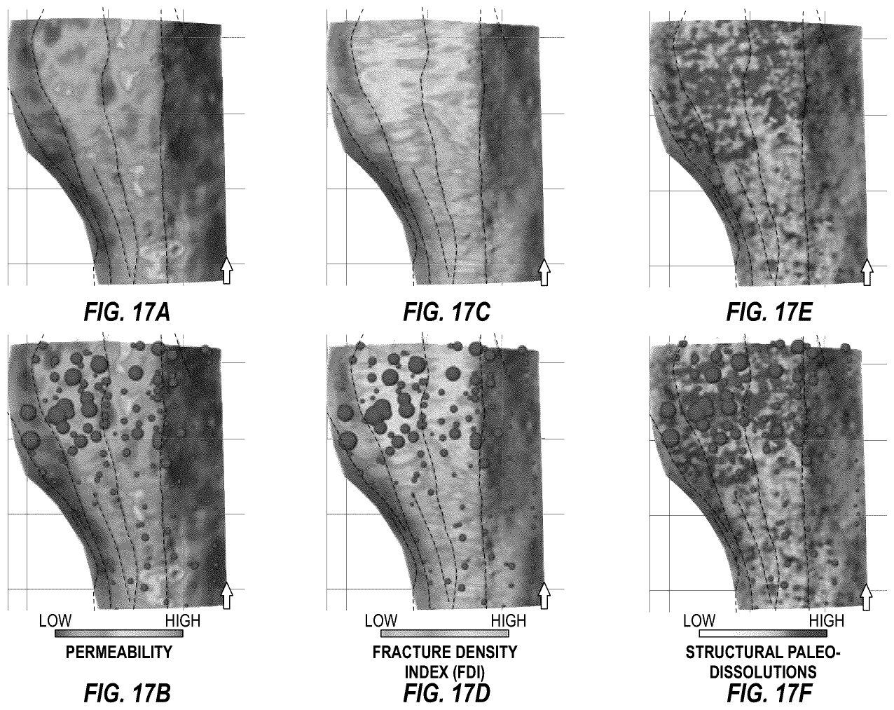

Additionally, as shown in FIG. 1, calibrated components may be determined (block 132). Spatial analysis between matrix permeability, fracture density index (FDI), and structural paleo dissolution (SPD) versus total flow capacity (PTA-KH), may facilitate the identification of sweet spots for natural fractures but also the structural paleo dissolution (SPD) that could impact the reservoir fluid behavior. By way of example, FIGS. 17A-17F depict various maps and overlays in accordance with an embodiment of the disclosure. FIG. 17A depicts a matrix permeability map, and FIG. 17B depicts total flow capacity (PTA-KH) overlaid on the matrix permeability map. FIG. 17C depicts a fracture density index (FDI), and FIG. 17D depicts total flow capacity (PTA-KH) overlaid on the fracture density index map. Finally, FIG. 17E depicts a structural paleo dissolution (SPD) map, and FIG. 17F depicts total flow capacity (PTA-KH) overlaid on the structural paleo dissolution (SPD) map. The larger circle size of the total flow capacity points corresponds to a larger PTA value.

The anomalous high PTA-KH (largest red circles) shown in FIGS. 17D and 17F can only be explained when considering the presence highly dense fracture regions and dissolutions, as the fracture density index (FDI) and structural paleo dissolution (SPD) model correctly indicate. By contrast, low matrix permeability in the same regions does not similarly explain the highest PTA-KH values measured in this field and shown in FIG. 17B.

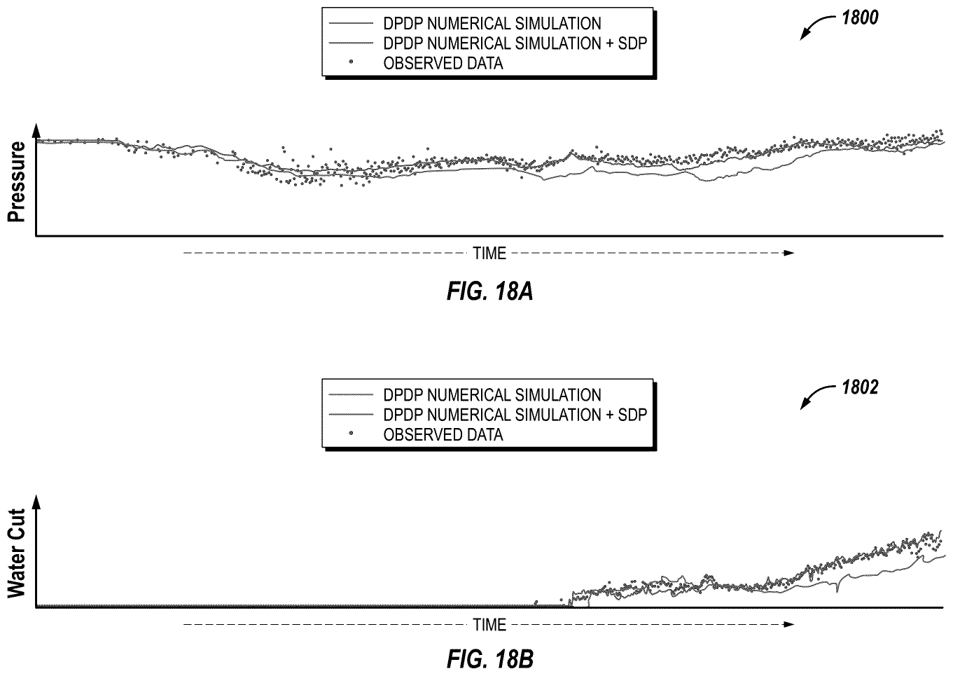

As described supra, a numerical simulation may be performed (block 134) incorporating the structural paleo dissolution (SPD) model. Fluid flow response in multiporosity reservoir simulation may be significantly enhanced by the incorporation of the Structural Paleo dissolution (SPD) model. For example, FIG. 18A is a plot 1800 of pressure and water cut vs. time that depicts the dynamic response in terms of pressure and watercut of a dual porosity/dual permeability scenario (matrix and fractures), while FIG. 18B is a plot 1802 of pressure and water cut vs time that depicts the dynamic response in terms of pressure and watercut of a multiporosity scenario which considers fractures and the Structural Paleo Dissolution model (DPDP+SPD) in accordance with an embodiment of the disclosure. As shown in FIG. 18B, the dynamic response based on a scenario in which the Structural Paleo Dissolution model was incorporated shows demonstrates significantly improved matching as compared to the dynamic response shown in FIG. 18A.

As mentioned infra, the identification of matrix permeability, fracture density index (FDI), and structural paleo dissolution (SPD), may facilitate the identification of sweet spots for natural fractures. The process 100 may include identifying a location (that is, a sweet spot) in a naturally fractured carbonate reservoir for a well using the structural paleo dissolution (SPD), matrix permeability, fracture density index (FDI), or any combination thereof. For example, a location for a well may be determined based on the presence or absence of natural fractures indicated by the techniques described in the disclosure. The process 100 may thus further include drilling a well in a subsurface geological structure at the determined location or controlling the drilling of the well in a subsurface geological structure at the determined location. In some embodiments, the process 100 may include performing a hydraulic fracturing stimulation operation in the drilled well or controlling the hydraulic fracturing stimulation operation.

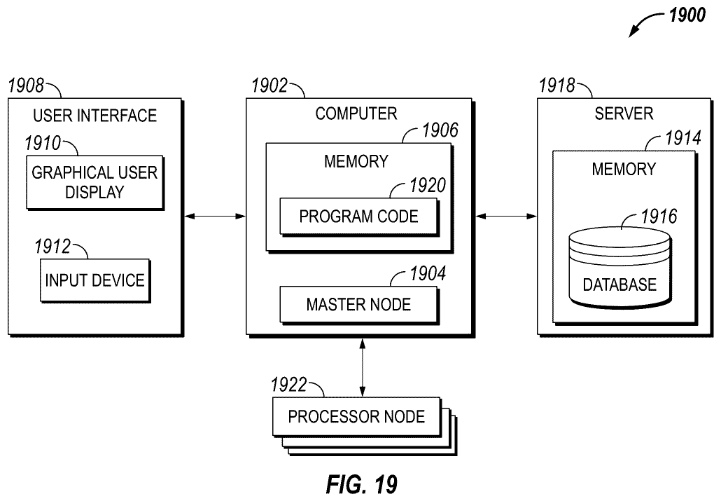

FIG. 19 depicts a data processing system 1900 that includes a computer 1902 having a processor 1904 and memory 1906 coupled to the processor 1904 to store operating instructions, control information and database records therein in accordance with an embodiment of the disclosure. The data processing system 1900 may be a multicore processor with nodes such as those from Intel Corporation or Advanced Micro Devices (AMD), or an HPC Linux cluster computer. The data processing system 1900 may also be a mainframe computer of any conventional type of suitable processing capacity such as those available from International Business Machines (IBM) of Armonk, N.Y., or other source. The data processing system 1900 may in cases also be a computer of any conventional type of suitable processing capacity, such as a personal computer, laptop computer, or any other suitable processing apparatus. It should thus be understood that a number of commercially available data processing systems and types of computers may be used for this purpose.

The computer 1902 is accessible to operators or users through user interface 1908 and are available for displaying output data or records of processing results obtained according to the present disclosure with an output graphic user display 1910. The output display 1910 includes components such as a printer and an output display screen capable of providing printed output information or visible displays in the form of graphs, data sheets, graphical images, data plots and the like as output records or images.

The user interface 1908 of computer 1902 also includes a suitable user input device or input/output control unit 1912 to provide a user access to control or access information and database records and operate the computer 1902. Data processing system 1900 further includes a database of data stored in computer memory, which may be internal memory 1906, or an external, networked, or non-networked memory as indicated at 1914 in an associated database 1916 in a server 1918.

The data processing system 1900 includes executable code 1920 stored in non-transitory memory 1906 of the computer 1902. The executable code 1920 according to the present disclosure is in the form of computer operable instructions causing the processor 1904 to determine a geological model, determine well scale fracture dissolution characterization, perform 3D fracture modeling, determine a 3D structural paleo dissolution (SPD) model, and perform calibration, validation, and numerical simulation using the 3D structural paleo dissolution (SPD) model, as discussed in the disclosure.

It should be noted that executable code 1920 may be in the form of microcode, programs, routines, or symbolic computer operable languages capable of providing a specific set of ordered operations controlling the functioning of the data processing system 1900 and direct its operation. The instructions of executable code 1920 may be stored in memory 1906 of the data processing system 1900, or on computer diskette, magnetic tape, conventional hard disk drive, electronic read-only memory, optical storage device, or other appropriate data storage device having a non-transitory computer readable storage medium stored thereon. Executable code 1920 may also be contained on a data storage device such as server 1920 as a non-transitory computer readable storage medium, as shown.

The data processing system 1900 may be include a single CPU, or a computer cluster as shown in FIG. 19, including computer memory and other hardware to make it possible to manipulate data and obtain output data from input data. A cluster is a collection of computers, referred to as nodes, connected via a network. A cluster may have one or two head nodes or master nodes 1904 used to synchronize the activities of the other nodes, referred to as processing nodes 1922. The processing nodes 1922 each execute the same computer program and work independently on different segments of the grid which represents the reservoir.

Ranges may be expressed in the disclosure as from about one particular value, to about another particular value, or both. When such a range is expressed, it is to be understood that another embodiment is from the one particular value, to the other particular value, or both, along with all combinations within said range.

Further modifications and alternative embodiments of various aspects of the disclosure will be apparent to those skilled in the art in view of this description. Accordingly, this description is to be construed as illustrative only and is for the purpose of teaching those skilled in the art the general manner of carrying out the embodiments described in the disclosure. It is to be understood that the forms shown and described in the disclosure are to be taken as examples of embodiments. Elements and materials may be substituted for those illustrated and described in the disclosure, parts and processes may be reversed or omitted, and certain features may be utilized independently, all as would be apparent to one skilled in the art after having the benefit of this description. Changes may be made in the elements described in the disclosure without departing from the spirit and scope of the disclosure as described in the following claims. Headings used in the disclosure are for organizational purposes only and are not meant to be used to limit the scope of the description.

What is claimed is:

1. A method for characterizing a naturally fractured carbonate reservoir, the method comprising:
obtaining a plurality of reservoir parameters representing a respectively plurality of properties of the naturally fractured carbonate reservoir;
forming a natural fracture model by processing the obtained plurality of reservoir parameters to identify the presence and extent of natural fractures at locations in the naturally fractured carbonate reservoir;
determining, by the data processing system and using the discrete fracture network, a fracture density index (FDI), wherein determining, using the discrete fracture network, a fracture density index (FDI) comprises generating a raster map from the discrete fracture network, the raster map representing a fracture density per area;
obtaining a well log characterizing the naturally fractured carbonate reservoir, wherein the well log comprises a borehole image log;
identifying structural paleo dissolution (SPD) indicators in the naturally fractured carbonate reservoir using the well log;
determining a three-dimensional structural paleo dissolution (SPD) model using the structural paleo dissolution (SPD) indicators and the fracture density index (FDI), the determining comprising identifying structural paleo dissolution (SPD) voids in the fracture density index (FDI); and
identifying a sweet spot for natural fractures in the naturally fractured carbonate reservoir using the three-dimensional structural paleo dissolution (SPD) model.

2. The method of claim 1, comprising:
obtaining a plurality of measurements from one or wells accessing the naturally fractured carbonate reservoir; and
determining the reservoir parameters from the plurality of measurements.

3. The method of claim 1, wherein the reservoir parameters comprise seismic attributes from seismic surveys of the subsurface geological structure.

4. The method of claim 1, wherein the reservoir parameters comprise rock and mechanical properties from geological models of the subsurface geological structure.

5. The method of claim 1, wherein the reservoir parameters comprise structural restoration models of the subsurface geological structure.

6. The method of claim 1, wherein the reservoir parameters comprise rock geological characterizations of the subsurface geological structure.

7. The method of claim 1, wherein the reservoir parameters comprise reservoir engineering measures obtained from production from the naturally fractured carbonate reservoir.

8. The method of claim 1, comprising determining a geological model of the naturally fractured carbonate reservoir using the reservoir parameters, wherein forming a natural fracture model by processing the obtained reservoir parameters comprises using a plurality of petrophysical properties from the geological model.

9. The method of claim 1, comprising drilling a well in a subsurface geological structure to a location in the naturally fractured carbonate reservoir based on the identified sweet spot.

10. The method of claim 1, comprising determining a total flow capacity using a rock matrix flow capacity for the naturally fractured carbonate reservoir, a fracture flow capacity for the for the naturally fractured carbonate reservoir, and a structural paleo dissolution (SPD) flow capacity for the naturally fractured carbonate reservoir.

11. The method of claim 1, comprising providing the three-dimensional structural paleo dissolution (SPD) model to a reservoir simulation for a determination of fluid flow response in the naturally fractured carbonate reservoir.

12. A non-transitory computer-readable storage medium having executable code stored thereon for characterizing a naturally fractured carbonate reservoir, the executable code comprising a set of instructions that causes a processor to perform operations comprising:
obtaining a plurality of reservoir parameters representing a respectively plurality of properties of the naturally fractured carbonate reservoir;
forming a natural fracture model by processing the obtained plurality of reservoir parameters to identify the presence and extent of natural fractures at locations in the naturally fractured carbonate reservoir;
determining, by the data processing system and using the discrete fracture network, a fracture density index (FDI), wherein determining, using the discrete fracture network, a fracture density index (FDI) comprises generating a raster map from the discrete fracture network, the raster map representing a fracture density per area;
obtaining a well log characterizing the naturally fractured carbonate reservoir, wherein the well log comprises a borehole image log;
identifying structural paleo dissolution (SPD) indicators in the naturally fractured carbonate reservoir using the well log;
determining a three-dimensional structural paleo dissolution (SPD) model using the structural paleo dissolution (SPD) indicators and the fracture density index (FDI), the determining comprising identifying structural paleo dissolution (SPD) voids in the fracture density index (FDI); and
identifying sweet spots for natural fractures to extract hydrocarbons from the naturally fractured carbonate reservoir using the three-dimensional structural paleo dissolution (SPD) model.

13. The non-transitory computer-readable storage medium of claim 12, the operations comprising:
obtaining a plurality of measurements from one or wells accessing the naturally fractured carbonate reservoir; and
determining the reservoir parameters from the plurality of measurements.

14. The non-transitory computer-readable storage medium of claim 12, wherein the reservoir parameters comprise seismic attributes from seismic surveys of the subsurface geological structure.

15. The non-transitory computer-readable storage medium of claim 12, wherein the reservoir parameters comprise rock and mechanical properties from geological models of the subsurface geological structure.

16. The non-transitory computer-readable storage medium of claim 12, wherein the reservoir parameters comprise structural restoration models of the subsurface geological structure.

17. The non-transitory computer-readable storage medium of claim 12, wherein the reservoir parameters comprise rock geological characterizations of the subsurface geological structure.

18. The non-transitory computer-readable storage medium of claim 12, wherein the reservoir parameters comprise reservoir engineering measures obtained from production from the naturally fractured carbonate reservoir.

19. The non-transitory computer-readable storage medium of claim 12, the operations comprising determining a geological model of the naturally fractured carbonate reservoir using the reservoir parameters, wherein forming a natural fracture model by processing the obtained reservoir parameters comprises using a plurality of petrophysical properties from the geological model.

20. The non-transitory computer-readable storage medium of claim 12, the operations comprising controlling the drilling of a well in a subsurface geological structure to a location in the naturally fractured carbonate reservoir based on the identified sweet spot.

21. A system for characterizing a naturally fractured carbonate reservoir, comprising:
a processor;
a non-transitory computer-readable memory accessible by the processor and having executable code stored thereon, the executable code comprising a set of instructions that causes a processor to perform operations comprising
obtaining a plurality of reservoir parameters representing a respectively plurality of properties of the naturally fractured carbonate reservoir;
forming a natural fracture model by processing the obtained plurality of reservoir parameters to identify the presence and extent of natural fractures at locations in the naturally fractured carbonate reservoir;
determining, by the data processing system and using the discrete fracture network, a fracture density index (FDI), wherein determining, using the discrete fracture network, a fracture density index (FDI) comprises generating a raster map from the discrete fracture network, the raster map representing a fracture density per area;
obtaining a well log characterizing the naturally fractured carbonate reservoir, wherein the well log comprises a borehole image log;
identifying structural paleo dissolution (SPD) indicators in the naturally fractured carbonate reservoir using the well log;
determining a three-dimensional structural paleo dissolution (SPD) model using the structural paleo dissolution (SPD) indicators and the fracture density index (FDI), the determining comprising identifying structural paleo dissolution (SPD) voids in the fracture density index (FDI); and
identifying sweet spots for natural fractures to extract hydrocarbons from the naturally fractured carbonate reservoir using the three-dimensional structural paleo dissolution (SPD) model.

22. The system of claim 21, the operations comprising:
obtaining a plurality of measurements from one or wells accessing the naturally fractured carbonate reservoir; and
determining the reservoir parameters from the plurality of measurements.

23. The system of claim 21, wherein the reservoir parameters comprise seismic attributes from seismic surveys of the subsurface geological structure.

24. The system of claim 21, wherein the reservoir parameters comprise rock and mechanical properties from geological models of the subsurface geological structure.

25. The system of claim 21, wherein the reservoir parameters comprise structural restoration models of the subsurface geological structure.

26. The system of claim 21, wherein the reservoir parameters comprise rock geological characterizations of the subsurface geological structure.

27. The system of claim 21, wherein the reservoir parameters comprise reservoir engineering measures obtained from production from the naturally fractured carbonate reservoir.

28. The system of claim 21, the operations comprising determining a geological model of the naturally fractured carbonate reservoir using the reservoir parameters, wherein forming a natural fracture model by processing the obtained reservoir parameters comprises using a plurality of petrophysical properties from the geological model.

29. The system of claim 21, the operations comprising controlling the drilling of a well in a subsurface geological structure to a location in the naturally fractured carbonate reservoir based on the identified sweet spot.
